(19) United States
(12) Patent Application Publication
(10) Pub. No.: US 2006/0076853 A1
(43) Pub. Date: Apr. 13, 2006

(54) Drive circuit for piezo ceramic device

(76) Inventors: Paul Weaver, Herts (GB); Simon Powell, Hertfordshire (GB)

Correspondence Address: Edward G Greive;Renner Kenner Greive Bobak Taylor & Weber, Fourth Floor, First National Tower, Akron, OH, 44308-1456, US

(21) Appl. No.: 10/511,256

(22) PCT Filed: Apr. 15, 2003
(86) PCT No.: PCT/GB03/01598

§ 371 Date: Nov. 16, 2005

(30) Foreign Application Priority Data
Apr. 15, 2002 (GB) 0208619.7
Feb. 28, 2003 (GB) 0304667.9

(51) Int. Cl. H01L 41/09

(52) U.S. Cl. 310/317

(57) ABSTRACT

A control circuit for controlling the operation of a piezo ceramic actuator comprising means for applying a voltage to the piezo ceramic actuator, the means arranged such that a linear charge is applied to the piezo ceramic device (10) which in turn produces a linear displacement of the piezo ceramic device. The control circuit preferably comprises four transistor switches (20) in H-bridge configuration.

The present invention relates to piezo ceramic devices and more particularly to a drive circuit for such a device.

Piezo ceramic devices are now well known but a characteristic of such devices is that in order to achieve high performance levels at low cost, it is necessary to operate at high field strengths. In this operating regime, non-linearity and hysteresis become important factors and their effective management is essential to obtain maximum performance.

It is an object of the present invention to provide a drive circuit which reduces the non-linearity effects.

In order that the present invention be more readily understood, an embodiment thereof will now be described with reference to the accompanying drawings in which:—

FIG. 1 shows an overall circuit diagram of a drive circuit according to the present invention;

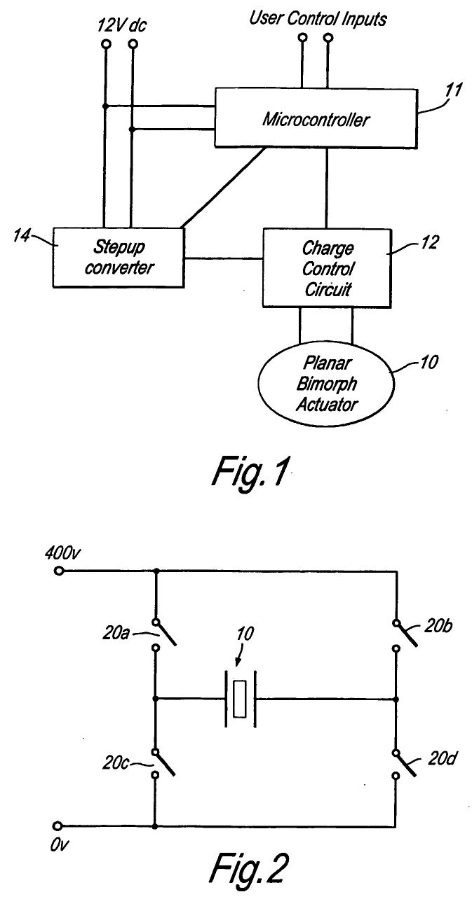

FIG. 2 shows a schematic diagram of a part of the drive circuit shown in FIG. 1;

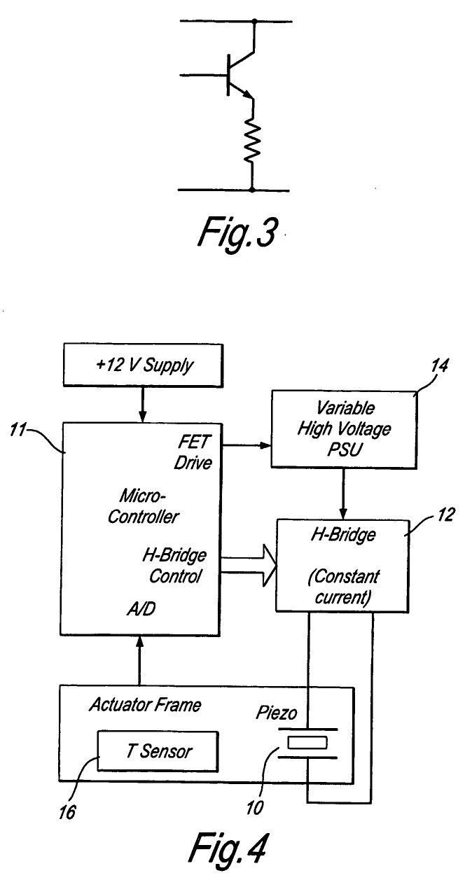

FIG. 3 shows a circuit diagram of a switch which is useful in the circuit part shown in FIG. 2;

FIG. 4 shows a further embodiment of the drive circuit according to the present invention;

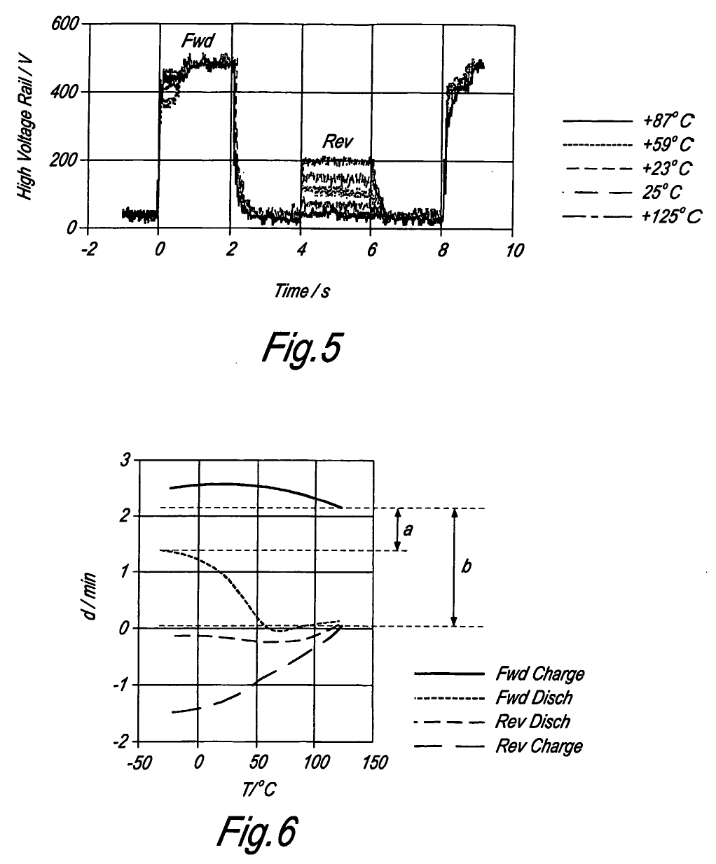

FIG. 5 shows a waveform diagram during a charge forward/reverse cycle in the circuit of FIG. 4; and

FIG. 6 shows a diagram showing the variation of forward and reverse positions of an actuator with temperature utilising the circuit of FIG. 4.

A preferred embodiment of drive circuit according to the present invention is shown in FIG. 1 where a piezo ceramic device, in this case a planar bimorph actuator 10 is driven by a micro controller 11 via a charge control circuit 12. The charge control circuit is supplied with power from a 12 volt dc supply via a step-up converter 14 which provides high voltage to the charge control circuit. The voltage output from the step-up converter is of the order of 100 to 600 volts preferably in the region of 20 to 400 volts.

The charge control circuit 12 is shown in more detail in FIG. 2 where it will be seen to be basically an H-bridge utilising four switches 20a, 20b, 20c, 20d which are usually operated in pairs to charge and discharge the piezo ceramic device 10.

We prefer to utilise transistor switches configured to operate as current sources for each of the switches 20 and this configuration is shown in more detail in FIG. 3. The use of such switches permits a linear charge to be applied to the piezo ceramic device 10 which in turn produces a linear characteristic when one considers displacement of the piezo ceramic device as compared with the applied charge. The use of such switches also permits a reverse bias to be applied.

In a further embodiment of the present invention, a temperature sensor 16 is provided in a feedback loop to the drive circuit and arranged such that the microcontroller unit 11 also contains an H-bridge control circuit which is connected to a H-bridge 12 and is responsive to signals from the temperature sensor 16 which is closely associated with the actuator 10.

In this embodiment, the unit 14 is preferably a variable high voltage source driven from a low voltage source such as a 12 volt supply, using the controller unit 11. This is shown in FIG. 4.

The temperature sensor 16 senses temperature variations of the piezo ceramic actuator 10 and provides the sensed data to the microcontroller 11 which adjusts the control regime of the piezo actuator 10 so as to reduce the non-linearity effects of any temperature variations.

The H-bridge 12 applies a reverse voltage to the piezo ceramic actuator 10 at constant current. The value of the reverse voltage is controlled by the control circuit in the controller unit 11 in response to signals from the temperature sensor 16. The average charge current is also controlled by the control circuit.

There is a very nearly linear relationship between coercive voltage of the material and temperature in the range −25° C. to +25° C. as the coercive voltage falls from 270 volts to 80 volts. This is used to apply a very simple algorithm for the control of the reverse voltage. A margin is built in to ensure operation well below the coercive voltage. The forward voltage is maintained at between 400 volts and 500 volts throughout the temperature range. This is shown in FIG. 5.

With the above arrangement, an almost constant linear charge rate can be obtained from most of the charge/discharge operation. The benefits of the control system are apparent from FIG. 6 which shows the variation in actuator position with temperature under different conditions. It also shows the actuator positions during the discharge parts of the cycle both from a forward position and a reverse position. The discharge from forward position will correspond approximately to the position reached without reverse biased being applied, ie in “unipolar” mode. It is clear that without reverse bias the performance across the full temperature range is compromised. This is indicated by the different between the arrows a and b.

The H-bridge switches are configured to provide the reverse bias to the piezo ceramic actuator. The actuator is held in a quiescent state by opening either switches 20a and 20b or 20c and 20d. When a reverse bias is required, the switches 20b and 20c are closed with the remaining switches being opened.

It will be appreciated that when the above control arrangement is utilised with an actuator whose materials and manufacturing method have been selected in order to provide optimum mechanical thermal expansion properties considerable advantages can be obtained.

1. A control circuit for controlling the operation of a piezo ceramic actuator comprising means for applying a voltage to the piezo ceramic actuator, the voltage applying means being arranged such that a charge is applied to the piezo ceramic device which in turn produces a displacement of the piezo ceramic device, characterised in that the voltage applying means is arranged to apply a reverse bias voltage to the actuator.

2. The control circuit according to claim 1, further comprising means for generating a control signal indicative of the temperature of the actuator and means for altering the amount of reverse bias voltage as a function of the control signal.

3. The control circuit according to claim 1, wherein the means for applying a voltage includes an H-bridge.

4. The control circuit according to claim 3, wherein the H-bridge is provided with a plurality of switches arranged to charge and discharge the piezo ceramic device.

5. The control circuit according to claim 4, wherein the plurality of switches are transistor switches.

6. The control circuit according to claim 3, wherein the H-bridge is configured to apply the reverse bias voltage to the actuator.

7. A piezo ceramic actuator arrangement according to claim 1 comprising a piezo ceramic actuator and a control circuit.

8. The control circuit according to claim 2, wherein the means for applying a voltage includes an H-bridge.

9. The control circuit according to claim 8, wherein the H-bridge is provided with a plurality of switches arranged to charge and discharge the piezo ceramic device.

10. The control circuit according to claim 9, wherein the plurality of switches are transistor switches.

11. The control circuit according to claim 8, wherein the H-bridge is configured to apply the reverse bias voltage to the actuator.

12. The control circuit according to claim 4, wherein the H-bridge is configured to apply the reverse bias voltage to the actuator.

13. The control circuit according to claim 9, wherein the H-bridge is configured to apply the reverse bias voltage to the actuator.

14. The control circuit according to claim 5, wherein the H-bridge is configured to apply the reverse bias voltage to the actuator.

15. The control circuit according to claim 10, wherein the H-bridge is configured to apply the reverse bias voltage to the actuator.
